(19) United States
(12) Patent Application Publication
(10) Pub. No.: US 2012/0171365 A1
(43) Pub. Date: Jul. 5, 2012

(54) FILM FORMING APPARATUS, FILM FORMING METHOD AND STORAGE MEDIUM

(75) Inventors: Shuji Azumo, Nirasaki-shi (JP); Yasuhiko Kojima, Nirasaki-shi (JP)

(73) Assignee: TOKYO ELECTRON LIMITED, Tokyo (JP)

(21) Appl. No.: 13/395,683

(22) PCT Filed: Aug. 27, 2010
(86) PCT No.: PCT/JP2010/064574

§ 371 Date: Mar. 13, 2012

(30) Foreign Application Priority Data
Sep. 17, 2009 (JP) 2009-215416

(51) Int. Cl. B05D 5/12; C23C 16/52; C23C 16/46

(52) U.S. Cl. 427/124; 118/725; 118/697

(57) ABSTRACT

The film forming apparatus includes a chamber 1; a heater 5 for heating a wafer W within the chamber 1; a film forming source vessel 31, provided outside the chamber 1, for accommodating cobalt carbonyl as a film forming source; a line 43 for transporting gaseous cobalt carbonyl from the film forming source vessel 31 to the chamber 1; an exhaust device 23 for depressurizing and exhausting an inside of the chamber 1; a cobalt carbonyl supply unit 38 for supplying the gaseous cobalt carbonyl from the film forming source vessel 31 to the chamber 1 via the line 43; a temperature controller 60 for controlling temperatures of the film forming source vessel 31 and the line 43 to be below a decomposition starting temperature of the cobalt carbonyl; and a CO gas supply unit 37 for supplying a CO gas into the film forming source vessel 31.

### TECHNICAL FIELD

The present disclosure relates to a film forming apparatus, a film forming method and a storage medium for forming a Co film by a CVD method.

### BACKGROUND ART

With the recent trend of a high-speed semiconductor device and a miniaturized wiring pattern, attention has been drawn to using Cu which has higher conductivity and higher electromigration resistance than Al as a wiring. Electroplating has been used to form the Cu wiring. Further, to easily bury the Cu wiring, it has been considered to change a seed of the Cu wiring formed by the electroplating from the conventionally used Cu to Co.

Further, in order to bring Si in contact with a source/drain electrode and a gate electrode in a MOS type semiconductor, CoSiₓ formed by silicidation of a Co film has been used.

As a Co film forming method, a physical vapor deposition (PVD) method using sputtering has generally been used. However, as semiconductor devices become miniaturized, it has become clear that the PVD method has a disadvantage such as a low step coverage.

Thus, as the Co film forming method, there has been used a chemical vapor deposition (CVD) method. In the CVD method, a Co film is formed on a substrate during a thermal decomposition reaction of a source gas containing Co or a reduction reaction of a reducing gas to the source gas. The Co film formed by this CVD method has a high step coverage and superior film forming properties within thin, long and deep patterns. For this reason, the Co film formed by the CVD method has superior properties within fine patterns and it is desirable to use the Co film as a seed layer of a Cu plating or a contact layer.

Regarding a Co film formed by a CVD method, it has been published that cobalt carbonyl (Co₂(CO)₈) is used as a film forming source and the Co₂(CO)₈ is thermally decomposed on a substrate provided in a chamber by supplying its vapor into the chamber (see, for example, Journal of The Electrochemical Society, 146(7) 2720-2724(1999)).

### DISCLOSURE OF THE INVENTION

### Problems to Be Solved by the Invention

However, since Co₂(CO)₈ has a vaporization temperature close to a decomposition temperature, Co₂(CO)₈ becomes decomposed while being vaporized and supplied into a chamber. Thus, it is difficult to form a Co film with high reproducibility. Further, if Co₂(CO)₈ becomes decomposed while being vaporized and transported, decomposed materials may remain within a pipe. Therefore, reliability of the apparatus becomes decreased, and the Co film becomes contaminated since carbon and oxygen are decomposed and these decomposed carbon and oxygen as ligands may infiltrate into the Co film.

Accordingly, the present disclosure provides a film forming apparatus and a film forming method capable of forming a Co film having fewer impurities with high reproducibility by suppressing decomposition of Co₂(CO)₈ as much as possible when Co₂(CO)₈ used as a film forming source is vaporized and transported. Further, the present disclosure provides a storage medium storing therein a program for performing the film forming method.

### Means for Solving the Problems

In accordance with a first aspect of the present disclosure, there is provided a film forming apparatus for forming a Co film on a substrate. Here, the film forming apparatus may include a processing chamber configured to accommodate therein a substrate; a heating unit configured to heat the substrate within the processing chamber; a film forming source vessel provided outside the processing chamber and configured to accommodate cobalt carbonyl as a film forming source; a line configured to transport cobalt carbonyl in gas phase from the film forming source vessel to the processing chamber; an exhaust device configured to depressurize and exhaust an inside of the processing chamber; a cobalt carbonyl supply unit configured to supply the cobalt carbonyl in gas phase from the film forming source vessel to the processing chamber via the line; a control unit configured to control temperatures of the film forming source vessel and the line to be below a decomposition starting temperature of the cobalt carbonyl; and a CO gas supply unit configured to supply a CO gas into the film forming source vessel.

In accordance with a second aspect of the present disclosure, there is provided a film forming method of forming a Co film on a substrate performed by a film forming apparatus. The film forming apparatus includes a processing chamber configured to accommodate therein a substrate; a heating unit configured to heat the substrate within the processing chamber; a film forming source vessel provided outside the processing chamber and configured to accommodate cobalt carbonyl as a film forming source; a line configured to transport cobalt carbonyl in gas phase from the film forming source vessel to the processing chamber; and an exhaust device configured to depressurize and exhaust an inside of the processing chamber. Further, the film forming method may include: supplying a CO gas into the film forming source vessel; vaporizing the cobalt carbonyl within the film forming source vessel and supplying the cobalt carbonyl in gas phase into the processing chamber via the line; controlling temperatures of an inside of the film forming source vessel and an inside of the line to be below a decomposition starting temperature of the cobalt carbonyl; and decomposing the cobalt carbonyl, in gas phase supplied into the processing chamber, on the heated substrate and depositing a Co film on the substrate.

In accordance with a third aspect of the present disclosure, there is provided a computer-readable storage medium having stored thereon computer-executable instructions that, in response to execution, cause a film forming apparatus to perform a film forming method. Here, the film forming apparatus may include a processing chamber configured to accommodate therein a substrate; a heating unit configured to heat the substrate within the processing chamber; a film forming source vessel provided outside the processing chamber and configured to accommodate cobalt carbonyl as a film forming source; a line configured to transport cobalt carbonyl in gas phase from the film forming source vessel to the processing chamber; and an exhaust device configured to depressurize and exhaust an inside of the processing chamber. Further, the film forming method may include supplying a CO gas into the film forming source vessel; vaporizing the cobalt carbonyl within the film forming source vessel and supplying the cobalt carbonyl in gas phase into the processing chamber via the line; controlling temperatures of an inside of the film forming source vessel and an inside of the line to be below a decomposition starting temperature of the cobalt carbonyl; and decomposing the cobalt carbonyl, in gas phase supplied into the processing chamber, on the heated substrate and depositing a Co film on the substrate.

### BRIEF DESCRIPTION OF THE DRAWINGS

FIG. 1 is a schematic cross-sectional view showing a film forming apparatus in accordance with an embodiment of the present disclosure; and

FIG. 2 is a chart showing a depressurization TG of Co₂(CO)₈.

### BEST MODE FOR CARRYING OUT THE INVENTION

Hereinafter, embodiments of the present disclosure will be described in detail with reference to the accompanying drawings.

<Configuration of a Film Forming Apparatus in Accordance with an Embodiment of the Present Disclosure>

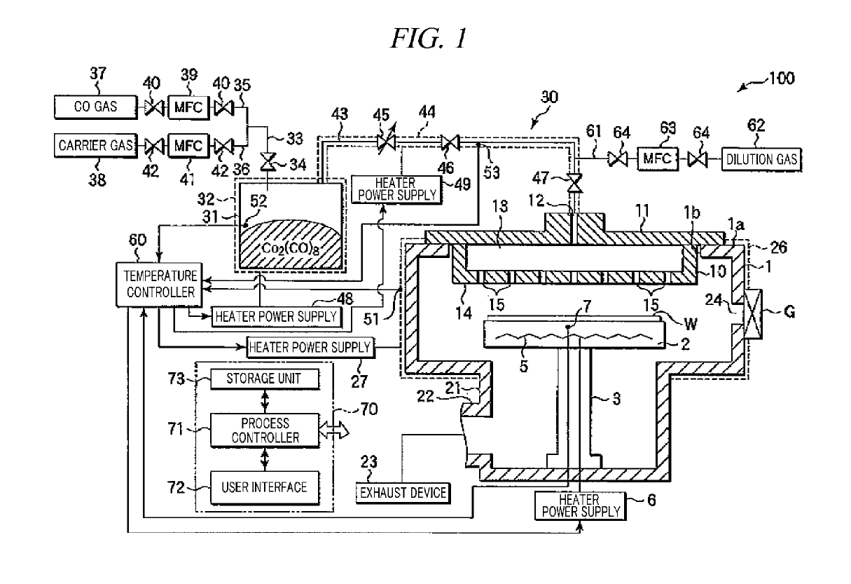

FIG. 1 is a schematic cross-sectional view showing a film forming apparatus in accordance with an embodiment of the present disclosure.

The film forming apparatus 100 may include an approximately cylindrical airtight chamber 1. In the chamber 1, a susceptor 2 configured to horizontally support a semiconductor wafer W serving as a target substrate may be positioned while being supported by a cylindrical supporting member 3 extending from a bottom of an exhaust chamber to be described later to a lower central portion thereof. This susceptor 2 may be made of ceramics such as AlN. Further, a heater 5 may be embedded in the susceptor 2 and this heater 5 may be connected with a heater power supply 6. Furthermore, a thermocouple 7 may be provided in a vicinity of an upper surface of the susceptor 2. A signal from the thermocouple 7 may be sent to a temperature controller 60 to be described later. The temperature controller 60 may transmit an instruction to the heater power supply 6 in response to the signal sent from the thermocouple 7, and the temperature controller 60 may control heating operation of the heater 5, so that the wafer W can be controlled to have a certain temperature. Moreover, three wafer elevating pins (not illustrated) may be provided in the susceptor 2 so as to protrude from and retract into a surface of the susceptor 2. When the wafer W is transferred, the three elevating pins may protrude from the surface of the susceptor 2.

On a ceiling wall 1a of the chamber 1, a circular hole 1b may be formed, and a shower head 10 may be inserted into the circular hole 1b so as to protrude into an inside of the chamber 1. The shower head 10 is configured to discharge a film forming gas supplied from a gas supply unit 30 to be described later into the chamber 1. In a ceiling plate 11 of the shower head 10, a gas inlet opening 12 through which the film forming gas is introduced may be provided. A gas diffusion space 13 may be formed within the shower head 10, and multiple gas discharge holes 15 may be formed in a lower plate 14 of the shower head 10. A gas introduced into the gas diffusion space 13 through the gas inlet opening 12 may be discharged into the chamber 1 through the gas discharge holes 15.

At a lower wall of the chamber 1, an exhaust chamber 21 protruding downwards may be provided. A side surface of the exhaust chamber 21 may be connected with an exhaust pipe 22, and the exhaust pipe 22 may be connected with an exhaust device 23 including a vacuum pump or a pressure control valve. By operating the exhaust device 23, the inside of the chamber 1 can be depressurized to a certain vacuum level.

At a side wall of the chamber 1, a transfer port 24 configured to transfer the wafer W between the chamber 1 and a wafer transfer chamber (not illustrated). A gate valve G configured to open and close the transfer port 24 may be provided. Further, at a wall of the chamber 1, a heater 26 may be provided to heat an inner wall of the chamber 1 during a film forming process. The heater 26 may be supplied with power from a heater power supply 27.

The gas supply unit 30 may include a film forming source vessel 31 for storing solid cobalt carbonyl (Co₂(CO)₈) serving as a film forming source. A heater 32 may be provided around the film forming source vessel 31, so that the solid cobalt carbonyl (Co₂(CO)₈) serving as a film forming source can be heated and vaporized. The heater 32 may be supplied with power from a heater power supply 48.

A gas inlet line 33 may be inserted into the film forming source vessel 31 from an upper side thereof. A valve 34 may be provided on the gas inlet line 33. The gas inlet line 33 may be branched into a CO gas line 35 and a carrier gas line 36. Further, the CO gas line 35 may be connected with a CO gas supply source 37 serving as a CO gas supply unit, and the carrier gas line 36 may be connected with a carrier gas supply source 38 serving as a cobalt carbonyl supply unit. At the CO gas line 35, a mass flow controller 39 as a flow rate controller and valves 40 placed in the front and back of the mass flow controller 39 may be arranged. At the carrier gas line 36, a mass flow controller 41 as a flow rate controller and valves 42 placed in the front and back of the mass flow controller 41 may be arranged. Desirably, as a carrier gas, an Ar gas or a N₂ gas may be used.

A CO gas may be introduced in order to suppress decomposition of vaporized cobalt carbonyl (Co₂(CO)₈). That is, Co₂(CO)₈ may produce CO through decomposition thereof. However, a reaction to produce CO through decomposition of Co₂(CO)₈ may be suppressed by increasing CO concentration through the supply of CO into the film forming source vessel 31. Meanwhile, the carrier gas may be introduced in order to transfer to the chamber 1 a Co₂(CO)₈ gas produced through vaporization thereof in the film forming source vessel 31. The CO gas may have a function of the carrier gas, and in this case, an additional carrier gas is not needed.

One end of a film forming source gas inlet line 43 may be inserted into the film forming source vessel 31 from an upper side thereof, and the other end of the film forming source gas inlet line 43 may be connected with the gas inlet opening 12. The Co₂(CO)₈ gas vaporized by the heater 32 may be transferred in the film forming source gas supply line 43 by the carrier gas, and supplied to the shower head 10 via the gas inlet opening 12. A heater 44 may be provided around the film forming source gas supply line 43. A power may be supplied to the heater 44 from a heater power supply 49. Further, at the film forming source gas supply line 43, a flow rate control valve 45, an opening/closing valve 46 on its downstream side, and an opening/closing valve 47 on a near side of the gas inlet opening 12 may be provided.

One end of a dilution gas supply line 61 may be connected with an upstream side of the film forming source gas supply line 43 from the valve 47, and the other end of the dilution gas supply line 61 may be connected with a dilution gas supply source 62 for supplying a dilution gas such as an Ar gas or a N₂ gas. At the dilution gas supply line 61, a mass flow controller 63 serving as a flow controller and valves 64 placed in the front and back of the mass flow controller 63 may be arranged. Further, the dilution gas may also function as a purge gas or a stabilization gas.

A thermocouple 51 may be provided at the wall of the chamber 1; a thermocouple 52 may be provided within the film forming source vessel 31; and a thermocouple 53 may be provided on the film forming source gas supply line 43. These thermocouples 51, 52 and 53 may be connected with the temperature controller 60. Temperature detection signals detected by the thermocouples including the above-described thermocouple 7 may be sent to the temperature controller 60. The temperature controller 60 may be connected with the above-described heater power supplies 6, 27, 48 and 49. The temperature controller 60 may send a control signal to the heater power supplies 6, 27, 48 and 49 in response to the detection signals from the thermocouples 7, 51, 52 and 53. As a result, it is possible to control a temperature of the susceptor 2, a temperature of the wall of the chamber 1, a temperature in the film forming source vessel 31 and a temperature in the film forming source gas supply line 43.

The cobalt carbonyl (Co₂(CO)₈) as a film forming source may be heated and vaporized in the film forming source vessel 31 by the heater 32, and then, the cobalt carbonyl (Co₂(CO)₈) in a gas phase may be transported into the chamber 1 while being heated in the film forming source gas supply line 43 by the heater 44. At this time, a heating temperature of the cobalt carbonyl (Co₂(CO)₈) may be controlled to be below a decomposition starting temperature by the temperature controller 60. To be specific, as described later, the decomposition starting temperature of the cobalt carbonyl obtained by a depressurization TG (thermogravimetric analyzer) is about 45° C. Therefore, it may be desirable to control the decomposition starting temperature to be below about 45° C.

Further, it may be desirable to control a temperature (a film forming temperature) of the wafer W during a film formation process to be in a range of from about 120° C. to about 300° C. It may also be desirable to control a temperature of the wall (inner wall) of the chamber 1 to be below a decomposition temperature of the Co₂(CO)₈ gas.

The film forming apparatus 100 may include a control unit 70. The control unit 70 may control each component such as the temperature controller 60, the exhaust device 23, the mass flow controllers, the flow rate control valves, and the valves. As for the temperature controller 60, the control unit 70 may set a temperature of a region to be controlled by the temperature controller 60. This control unit 70 may include a process controller 71 equipped with a micro processor (a computer), a user interface 72, and a storage unit 73. The process controller 71 is electrically connected with each component of the film forming apparatus 100 to control each component. The user interface 72 may be connected with the process controller 71 and may include a keyboard with which an operator may input a command to operate each component of the film forming apparatus 100 or a display which visualizes and displays an operation status of each component of the film forming apparatus 100. The storage unit 73 may be connected with the process controller 71. This storage unit 73 may store a control program for performing various processes to be carried out in the film forming apparatus 100 under the control of the process controller 71, or the storage unit 73 may store a control program, i.e., a process recipe or various data, for performing a certain process by each component of the film forming apparatus 100 depending on processing conditions. The process recipe may be stored in a storage medium (not illustrated) in the storage unit 73. The storage medium may be a fixed medium such as a hard disk or may be a portable storage medium such as a CD-ROM, a DVD and a flash memory. Otherwise, the recipe may be received appropriately from another apparatus via, for example, a dedicated line.

Further, if necessary, a certain process recipe may be retrieved from the storage unit 53 in response to a command from the user interface 52 and executed by the process controller 51. Accordingly, a desired process may be performed in the film forming apparatus 100 under the control of the process controller 71.

<Explanation of a Film Forming Method Performed by a Film Forming Apparatus in Accordance with the Present Embodiment>

Hereinafter, there will be explained a film forming method performed by the film forming apparatus configured as described above.

First, the film forming source vessel 31 may be charged with cobalt carbonyl (Co₂(CO)₈) in a solid phase as a film forming source, and the temperature of the susceptor 2 within the chamber 1 and the temperature of the wall of the chamber 1 may be set to be a film formation temperature. Then, the gate valve G may be opened and the wafer W may be loaded into the chamber 1 by a non-illustrated transfer unit, and may be mounted on the susceptor 2. In case of using the Co film as the seed of the Cu wiring to be formed by electroplating, a wafer W having thereon a SiOxCy-based insulating film (x and y are positive numbers) or an organic insulating film serving as an underlayer, and an Al, Cu or W conductor serving as an underlying wiring may be used. Further, in case of using the Co film as the contact layer, a wafer having thereon an exposed silicon substrate surface to be made as a source/drain electrode or a polysilicon film may be used.

Subsequently, the inside of the chamber 1 may be exhausted by the exhaust device 23 so as to control a pressure within the chamber 1 in a range of from about 10 Pa to about 5000 Pa (from about 0.075 Torr to about 37.5 Torr), and the susceptor 2 may be heated by the heater 5 so that a temperature of the susceptor 2 (a wafer temperature) may be controlled, desirably, in a range of from about 120° C. to about 300° C.

Thereafter, the valve 46 may be closed and the valves 47 and 64 may be opened so as to supply a dilution gas from the dilution gas supply source 62 into the chamber 1, so that stabilization may be performed.

The film forming source vessel 31 and the film forming source gas supply line 43 may be heated by the heaters 32 and 44, respectively, while strictly controlling temperatures thereof to be below the decomposition starting temperature of the cobalt carbonyl (Co₂(CO)₈). After performing stabilization by using the dilution gas for a certain time, the supply of the dilution gas may be stopped, or while the dilution gas is supplied at a certain flow rate, the CO gas and the carrier gas may be supplied into the film forming source vessel 31. At the same time, the valve 46 may be opened so as to introduce the Co₂(CO)₈ gas vaporized within the film forming source vessel 31 through the film forming source gas supply line 43 by the carrier gas. Then, the Co₂(CO)₈ gas may be supplied into the chamber 1 via the shower head 10.

The Co₂(CO)₈ gas supplied into the chamber 1 may reach a surface of the wafer W heated to a certain temperature by the heater 5 within the susceptor 2. Then, the Co₂(CO)₈ gas may be thermally decomposed on the surface of the wafer W and a Co film may be formed thereon.

After the Co film is formed as described above, a purge process may be performed. In the purge process, the supply of Co₂(CO)₈ may be stopped by stopping the supply of the carrier gas into the film forming source vessel 31. Then, the vacuum pump of the exhaust device 23 may be operated and the dilution gas as a purge gas may be introduced from the dilution gas supply source 62 into the chamber 1 so as to purge the chamber 1. In this case, in order to purge the chamber 1 as quickly as possible, it may be desirable to intermittently supply the carrier gas.

After the purge process is ended, the gate valve G may be opened and the wafer W may be unloaded by the non-illustrated transfer unit through the transfer port 24. In this way, a series of processes for one sheet of the wafer W may be ended.

When the Co film is formed as describe above, the film forming source vessel 31 and the film forming source gas supply line 43 may be controlled to have temperatures below the decomposition starting temperature of the cobalt carbonyl (Co₂(CO)₈) gas. Thus, while the cobalt carbonyl (Co₂(CO)₈) gas produced by vaporization within the film forming source vessel 31 is supplied from the film forming source vessel 31 into the chamber 1 through the film forming source gas supply line 43, the temperature of the cobalt carbonyl (Co₂(CO)₈) gas may be maintained below the decomposition starting temperature thereof, and decomposition of Co₂(CO)₈ gas can be suppressed. Further, by introducing the CO gas into the film forming source vessel 31, a concentration of CO may be increased in the film forming source vessel 31, so that a reaction of producing CO through decomposition of Co₂(CO)₈ can be suppressed.

As described above, a temperature at which Co₂(CO)₈ is vaporized and a temperature at which the produced Co₂(CO)₈ gas is transferred into the chamber 1 may be set to be below the decomposition starting temperature of the Co₂(CO)₈ gas. At the same time, the CO gas capable of suppressing decomposition of the Co₂(CO)₈ gas may be introduced into the film forming source vessel 31. Therefore, it may be possible to efficiently suppress a decomposition reaction of Co₂(CO)₈ gas while Co₂(CO)₈ is vaporized and supplied into the chamber 1. Further, it is also possible to allow a decomposition reaction to occur almost only on the wafer W. For this reason, it may be possible to form the Co film with reproducibility.

If the Co₂(CO)₈ gas is decomposed before it reaches the wafer W, CO as a ligand may be further decomposed to produce carbon and oxygen. Further, Co₂(CO)ₓ under the decomposition process may be deposited on the wafer W, and, thus, carbon and oxygen may be produced on the wafer W. Therefore, these carbon and oxygen may be infiltrated into the CO film as impurities. However, as described in the present embodiment, by suppressing decomposition of the Co₂(CO)₈ gas until the Co₂(CO)₈ gas reaches the wafer W, the CO gas produced on the surface of the wafer W through the decomposition of Co₂(CO)₈ may not be further decomposed and may be quickly discharged from the chamber 1. Therefore, it is possible to prevent carbon and oxygen from infiltrating into the Co film as impurities, and it is possible to obtain the Co film having fewer impurities.

Further, since the decomposition of the Co₂(CO)₈ gas may be suppressed until the Co₂(CO)₈ gas reaches the wafer W, it may be possible to avoid a decrease in reliability of the apparatus caused by decomposed materials of the Co₂(CO)₈ gas remaining in a pipe or the like. Moreover, since the Co film formed in the chamber 1 may be suppressed to a minimum, it may be possible to provide high maintainability to the apparatus.

When considering only a temperature control, for the sake of safety, a vaporization temperature of Co₂(CO)₈ gas (a temperature of the film forming source vessel 31) and a transport temperature of Co₂(CO)₈ (a temperature within the film forming source gas supply line 43) may need to be controlled to be a temperature of, for example, about 35° C. or less, and as a result, only a limited amount of the Co₂(CO)₈ gas may be produced. However, in accordance with the present embodiment, in addition to the temperature control, by introducing the CO gas into the film forming source vessel 31, it becomes possible to control the vaporization temperature and the transport temperature of Co₂(CO)₈ to be higher than a safe temperature but below the decomposition starting temperature. Accordingly, a production amount of the Co₂(CO)₈ gas can be increased, and throughput of the film forming process can also be increased.

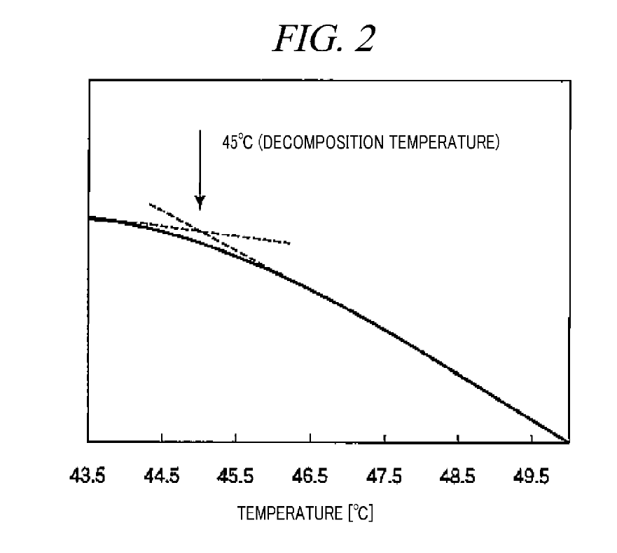

Generally, a decomposition temperature of a compound such as the Co₂(CO)₈ gas can be obtained by DTA (Differential Thermal Analysis) and a decomposition starting temperature of the Co₂(CO)₈ gas obtained by DTA may be about 51° C. which is very close to 52° C. described in a non-patent document (THE MERCK 10th edition 3067) as a decomposition starting temperature. However, according to a result of a strict analysis on the decomposition temperature based on a weight change by a depressurization TG, the decomposition starting temperature is about 45° C. as depicted in FIG. 2. It can thus be determined from this result that it may be desirable to control heating temperature of the film forming source vessel 31 and the film forming source gas supply line 43 to be below about 45° C. Since the lowest limit may be substantially room temperature, it may be desirable to control the temperatures to be in a range of from room temperature to below about 45° C.

As for the temperature (the film forming temperature) of the wafer W during the film formation, since a decomposition ending temperature of the Co₂(CO)₈ gas obtained by the DTA is about 120° C., if the film forming temperature is about 120° C. or higher, the Co₂(CO)₈ gas can be completely decomposed into Co and CO. Meanwhile, if the film forming temperature exceeds about 300° C., Co may be aggregated. For this reason, desirably, the film forming temperature may be in a range of from about 120° C. to about 300° C.

It may be desirable that the temperature of the wall (inner wall) of the chamber 1 is below the decomposition temperature of the Co₂(CO)₈ gas. Thus, it may be possible to prevent the Co₂(CO)₈ gas from being decomposed and prevent increase of impurities in the Co film even if the Co₂(CO)₈ gas reaches the inner wall of the chamber 1.

Desirably, the Co film formed as described above may serve as a seed film of a Cu wiring formed by electroplating. Further, the Co film may be used as an underlying film of a CVD-Cu film. Furthermore, in case of using the Co film as a contact layer, the Co film may be formed on a surface of a silicon substrate or a surface of a polysilicon film by the above-described method. Then, a heat treatment for silicidation may be performed under an inert gas atmosphere or a reduction gas atmosphere. In this case, desirably, a temperature of the heat treatment may be in a range of from about 450° C. to about 800° C.

As described above, by introducing the CO gas into the film forming source vessel, and at the same time, by controlling temperatures of the film forming source vessel and the line to be below the decomposition starting temperature of cobalt carbonyl, it may be possible to sufficiently suppress decomposition of the cobalt carbonyl until the cobalt carbonyl reaches a substrate within a processing chamber. Therefore, a highly reproducible film can be formed. Further, it may be possible to suppress infiltration of decomposed materials of the cobalt carbonyl gas into the Co film as impurities. Accordingly, the Co film having fewer impurities can be formed.

<Other Applications of the Present Disclosure>

The present disclosure is not limited to the above-described embodiment and can be modified in various ways. By way of example, a method of supplying cobalt carbonyl as a film forming source is not limited to the method of the above-described embodiment, and other various methods can be adopted.

Although there has been explained a case in which a semiconductor wafer is used as a target substrate, the target substrate is not limited thereto and other substrates such as a flat panel display (FPD) can be used.

What is claimed is:

1. A film forming apparatus for forming a Co film on a substrate, the apparatus comprising:
a processing chamber configured to accommodate therein a substrate;
a heating unit configured to heat the substrate within the processing chamber;
a film forming source vessel provided outside the processing chamber and configured to accommodate cobalt carbonyl as a film forming source;
a line configured to transport cobalt carbonyl in gas phase from the film forming source vessel to the processing chamber;
an exhaust device configured to depressurize and exhaust an inside of the processing chamber;
a cobalt carbonyl supply unit configured to supply the cobalt carbonyl in gas phase from the film forming source vessel to the processing chamber via the line;
a control unit configured to control temperatures of the film forming source vessel and the line to be below a decomposition starting temperature of the cobalt carbonyl; and
a CO gas supply unit configured to supply a CO gas into the film forming source vessel.

2. The film forming apparatus of claim 1,
wherein the control unit controls the temperatures of the film forming source vessel and the line to be below about 45° C.

3. The film forming apparatus of claim 1,
wherein the heating unit heats the substrate in a range of from about 120° C. to about 300° C.

4. A film forming method of forming a Co film on a substrate performed by a film forming apparatus including a processing chamber configured to accommodate therein a substrate, a heating unit configured to heat the substrate within the processing chamber, a film forming source vessel provided outside the processing chamber and configured to accommodate cobalt carbonyl as a film forming source, a line configured to transport cobalt carbonyl in gas phase from the film forming source vessel to the processing chamber, and an exhaust device configured to depressurize and exhaust an inside of the processing chamber, the film forming method comprising:
supplying a CO gas into the film forming source vessel;
vaporizing the cobalt carbonyl within the film forming source vessel and supplying the cobalt carbonyl in gas phase into the processing chamber via the line;
controlling temperatures of an inside of the film forming source vessel and an inside of the line to be below a decomposition starting temperature of the cobalt carbonyl; and
decomposing the cobalt carbonyl, in gas phase supplied into the processing chamber, on the heated substrate and depositing a Co film on the substrate.

5. The film forming method of claim 4,
wherein the temperatures of the inside of the film forming source vessel and the inside of the line are controlled to be below about 45° C.

6. The film forming method of claim 4,
wherein, in the depositing a Co film, a heating temperature of a surface of the substrate is controlled to be in a range of from about 120° C. to about 300° C.

7. The film forming method of claim 4,
wherein the Co film is formed on silicon, and after a film formation of the Co film, a heat treatment for silicidation is performed under an inert gas atmosphere or a reduction gas atmosphere.

8. A computer-readable storage medium having stored thereon computer-executable instructions that, in response to execution, cause a film forming apparatus to perform a film forming method,
wherein the film forming apparatus comprises:
a processing chamber configured to accommodate therein a substrate;
a heating unit configured to heat the substrate within the processing chamber;
a film forming source vessel provided outside the processing chamber and configured to accommodate cobalt carbonyl as a film forming source;
a line configured to transport cobalt carbonyl in gas phase from the film forming source vessel to the processing chamber; and
an exhaust device configured to depressurize and exhaust an inside of the processing chamber, and
the film forming method comprises:
supplying a CO gas into the film forming source vessel;
vaporizing the cobalt carbonyl within the film forming source vessel and supplying the cobalt carbonyl in gas phase into the processing chamber via the line;
controlling temperatures of an inside of the film forming source vessel and an inside of the line to be below a decomposition starting temperature of the cobalt carbonyl; and
decomposing the cobalt carbonyl, in gas phase supplied into the processing chamber, on the heated substrate and depositing a Co film on the substrate.
